(19) United States
(12) Patent Application Publication
(10) Pub. No.: US 2025/0248067 A1
(43) Pub. Date: Jul. 31, 2025

(54) SWITCH STRUCTURE, METHOD FOR PREPARING SAME, AND RF CHIP

(71) Applicant: BOE Technology Group Co., Ltd., Beijing (CN)

(72) Inventors: Qiuyun Tan, Beijing (CN); Hu Meng, Beijing (CN); Xiangyang Zhu, Beijing (CN)

(73) Assignee: BOE Technology Group Co., Ltd., Beijing (CN)

(21) Appl. No.: 18/694,526

(22) PCT Filed: Aug. 28, 2023
(86) PCT No.: PCT/CN2023/115291

§ 371 Date: Mar. 22, 2024

(51) Int. Cl. H10D 30/67; H10D 1/47; H10D 30/01; H10D 64/23; H10D 64/27; H10D 86/01

(52) U.S. Cl. CPC H10D 30/6731; H10D 1/47; H10D 30/0323; H10D 64/257; H10D 64/519; H10D 86/01; H10D 30/6744; H10D 30/6758

(57) ABSTRACT

The disclosure provides a switch structure, a method for preparing the same, and an RF chip. The switch structure includes a glass substrate; at least one switch sub-circuit located on the glass substrate and including at least one switch unit, where the switch unit includes a transistor, a resistor and a power supply device, a gate of the transistor is electrically connected to the resistor, the resistor is electrically connected to the power supply device, a first electrode of at least one transistor is electrically connected to an in pad, and a second electrode of at least one transistor is electrically connected to an out pad; a silicon material layer bonded to the glass substrate and including a conducted region, where a portion of the conducted region is configured to electrically connect the gate of the transistor and the resistor.

### TECHNICAL FIELD

The disclosure relates to the technical field of switches, and particularly to a switch structure, a method for preparing the same, and an RF chip.

### BACKGROUND

An Radio Frequency (RF) switch can connect any one or more of multiple RF signals through control logic to achieve switching between different types of paths, including switching between receiving and transmitting, and switching between different frequency bands etc., so as to achieve the purpose of sharing an antenna and saving the cost of a terminal product.

At present, the commonly used RF switch technology is RF SOI (Radio Frequency Silicon On Insulator). RF switch products of SOG (Silicon On Glass) technology are rarely seen.

### SUMMARY

An embodiment of the disclosure adopts the following technical solution.

In a first aspect, an embodiment of the disclosure provides a switch structure including:
a glass substrate;
at least one switch sub-circuit located on the glass substrate, where the switch sub-circuit includes at least one switch unit; the switch unit includes a transistor and a resistor; a gate of the transistor is electrically connected to the resistor; the resistor is electrically connected to a power supply device; a first electrode of at least one transistor is electrically connected to an in pad, and a second electrode of at least one transistor is electrically connected to an out pad; and
a silicon material layer located on and bonded to the glass substrate, where the silicon material layer includes a conducted region; a portion of the conducted region is configured to electrically connect the gate of the transistor and the resistor; and an ion doping concentration of the conducted region is greater than or equal to 1×10¹⁸ cm⁻³.

In at least one embodiment of the disclosure, at least one of the first electrode of the transistor, the second electrode of the transistor, and the gate of the transistor includes an interdigital structure.

In at least one embodiment of the disclosure, the first electrode of the transistor, the second electrode of the transistor, and the gate of the transistor all include the interdigital structure, and an orthographic projection of the gate of the transistor partially overlaps with an orthographic projection of one of the first electrode of the transistor and the second electrode of the transistor on the glass substrate.

In at least one embodiment of the disclosure, the first electrode of the transistor and the second electrode of the transistor include the interdigital structure, and the gate of the transistor includes a serpentine structure; and

an orthographic projection of the gate of the transistor on the glass substrate is located between an orthographic projection of the first electrode of the transistor on the glass substrate and an orthographic projection of the second electrode of the transistor on the glass substrate, and the orthographic projections of the gate of the transistor, the first electrode of the transistor, and the second electrode of the transistor on the glass substrate do not overlap each other.

In at least one embodiment of the disclosure, a channel width-to-length ratio of the transistor is greater than or equal to 5000.

In at least one embodiment of the disclosure, the silicon material layer includes a monocrystalline silicon sub-layer.

In at least one embodiment of the disclosure, wherein the silicon material layer includes a monocrystalline silicon sub-layer and an amorphous silicon sub-layer successively arranged on the glass substrate; and a thickness of the amorphous silicon sub-layer is less than a thickness of the monocrystalline silicon sub-layer.

In at least one embodiment of the disclosure, wherein the switch sub-circuit includes an in pad and an out pad.

In at least one embodiment of the disclosure, the switch sub-circuit includes a first switch unit; the first switch unit includes a first transistor and a first resistor; and the power supply device includes a first power supply device; and

a first electrode of the first transistor is electrically connected to the in pad; a second electrode of the first transistor is electrically connected to the out pad; a gate of the first transistor is electrically connected to a first terminal of the first resistor; and the first power supply device is electrically connected to a ground terminal and a second terminal of the first resistor, respectively.

In at least one embodiment of the disclosure, wherein the switch sub-circuit includes a second switch unit and a third switch unit; the second switch unit includes a second transistor and a second resistor; the third switch unit includes a third transistor and a third resistor; the power supply device includes a second power supply device and a third power supply device;

a first electrode of the second transistor and a first electrode of the third transistor are electrically connected to the in pad; a second electrode of the second transistor is electrically connected to the out pad; a gate of the second transistor is electrically connected to a first terminal of the second resistor; and the second power supply device is electrically connected to a ground terminal and a second terminal of the second resistor, respectively; and

a gate of the third transistor is electrically connected to a first terminal of the third resistor; the third power supply device is electrically connected to a ground terminal and a second terminal of the third resistor, respectively; and a second electrode of the third transistor is electrically connected to the ground terminal.

In at least one embodiment of the disclosure, the switch sub-circuit includes a fourth switch unit, a fifth switch unit, a sixth switch unit and a seventh switch unit;

the fourth switch unit includes a fourth transistor and a fourth resistor; the fifth switch unit includes a fifth transistor and a fifth resistor; the sixth switch unit includes a sixth transistor and a sixth resistor; the seventh switch unit includes a seventh transistor and a seventh resistor; and the power supply device includes a fifth power supply device and a sixth power supply device; and

wherein the fourth switch unit and the sixth switch unit share the sixth power supply device, and the fifth switch unit and the seventh switch unit share the fifth power supply device.

In at least one embodiment of the disclosure, the switch sub-circuit includes one in pad and two out pads.

In at least one embodiment of the disclosure, wherein the switch sub-circuit includes two in pads and one out pad.

In at least one embodiment of the disclosure, wherein a first electrode of the fourth transistor and a first electrode of the fifth transistor are electrically connected to a first one of the out pads; a second electrode of the fourth transistor is electrically connected to a ground terminal; a second electrode of the fifth transistor is electrically connected to the in pad; a gate of the fourth transistor is electrically connected to a first terminal of the fourth resistor; and a gate of the fifth transistor is electrically connected to a first terminal of the fifth resistor; and

a first electrode of the sixth transistor and a first electrode of the seventh transistor are electrically connected to a second one of the out pads; a second electrode of the sixth transistor is electrically connected to the in pad; a second electrode of the seventh transistor is electrically connected to the ground terminal; a gate of the sixth transistor is electrically connected to a first terminal of the sixth resistor; and a gate of the seventh transistor is electrically connected to a first terminal of the seventh resistor.

In at least one embodiment of the disclosure, a second terminal of the fourth resistor and a second terminal of the sixth resistor are electrically connected to the sixth power supply device; and a second terminal of the fifth resistor and a second terminal of the seventh resistor are electrically connected to the fifth power supply device.

In at least one embodiment of the disclosure, the switch structure includes a plurality of switch sub-circuits arranged in an array on the glass substrate.

In at least one embodiment of the disclosure, the transistor includes a plurality of sub-transistors arranged in series; a gate of each sub-transistor is connected to the resistor; a first electrode of the sub-transistor and a second electrode of the sub-transistor include an interdigital structure; and the gate of the sub-transistor includes a serpentine structure.

In at least one embodiment of the disclosure, the switch structure includes:
the silicon material layer including a first semiconductor pattern and a second semiconductor pattern;
a gate insulating layer covering the silicon material layer;
a gate layer located on a side of the gate insulating layer away from the glass substrate and including the gate of the transistor;
an inter level dielectric layer covering the gate layer; and
a source-drain conductive layer located on a side of the inter level dielectric layer away from the glass substrate and including the first electrode and the second electrode of the transistor; and
wherein the first semiconductor pattern and the second semiconductor pattern include a semiconductor region and conducted regions located on two sides of the semiconductor region; the first electrode of the transistor is electrically connected to one of the conducted regions in the first semiconductor pattern; the second electrode of the transistor is electrically connected to the other one of the conducted regions in the first semiconductor pattern; the semiconductor region in the first semiconductor pattern serves as a channel region of the transistor; and the semiconductor region in the second semiconductor pattern serves as the resistor.

In at least one embodiment of the disclosure, the source-drain conductive layer further includes a first trace, a second trace and a third trace, wherein the first trace is electrically connected to one of the second trace and the third trace; and

the first trace is electrically connected to the gate of the transistor; the second trace is electrically connected to one of the conducted regions in the second semiconductor pattern; and the third trace is electrically connected to the other one of the conducted regions in the second semiconductor pattern.

In at least one embodiment of the disclosure, for at least one transistor, a first electrode of the transistor includes an interdigital structure;

the first electrode of the transistor includes a first connection portion and N-2 first extension portions arranged in the same row; an extension direction of the first connection portion intersects with an extension direction of the first extension portions; an arrangement direction of the first extension portions is the same as the extension direction of the first connection portion; the first connection portion is located on the same side of each of the first extension portions and connects each of the first extension portions together; N is a positive integer and is greater than or equal to 4; and

an orthographic projection of each of the first extension portions on the glass substrate at least partially overlaps with an orthographic projection of the first semiconductor pattern on the glass substrate.

In at least one embodiment of the disclosure, for at least one transistor, a second electrode of the transistor includes an interdigital structure;

the second electrode of the transistor includes a second connection portion and N-3 second extension portions arranged in the same row; an extension direction of the second connection portion is the same as the extension direction of the first connection portion; an arrangement direction of the second extension portions is the same as the arrangement direction of the first extension portions; the second connection portion is located on the same side of each of the second extension portions and connects each of the second extension portions together; and

an orthographic projection of each of the second extension portions on the glass substrate at least partially overlaps with the orthographic projection of the first semiconductor pattern on the glass substrate.

In at least one embodiment of the disclosure, for at least one transistor, a gate of the transistor includes an interdigital structure;

the gate of the transistor includes a third connection portion and N third extension portions arranged in the same row; an extension direction of the third connection portion intersects with an extension direction of the third extension portions; the third connection portion is located at the same side of each of the third extension portions and connects each of the third extension portions together; an orthographic projection of each of the third extension portions on the glass substrate at least partially overlaps with the orthographic projection of the first semiconductor pattern on the glass substrate; and an orthographic projection of the third connection portion on the glass substrate partially overlaps with orthographic projections of all the second extension portions on the glass substrate; and

wherein the orthographic projections of the first extension portions, the third extension portions, and the second extension portions on the glass substrate are alternately arranged in sequence along the extension direction of the third connection portion.

In at least one embodiment of the disclosure, for at least one transistor, a gate of the transistor includes a serpentine structure;

the gate of the transistor has a first bent portion and a second bent portion alternately arranged; the gate of the transistor further has a first opening portion and a second opening portion alternately arranged, so that the gate of the transistor has the serpentine structure; an outer contour of the first opening portion is arranged on the first bent portion; an outer contour of the second opening portion is arranged on the second bent portion; and the openings of the first opening portion and the second opening portion face opposite directions; and

wherein the outer contour of the first opening portion and the outer contour of the second opening portion include a combination of a plurality of straight line segments, a combination of a straight line segment and an arc, or an arc.

In at least one embodiment of the disclosure, an outer contour of a side of the first bent portion on which the first opening portion is not provided and an outer contour of a side of the second bent portion on which the second opening portion is not provided include a combination of a plurality of straight line segments, a combination of a straight line segment and an arc, or an arc.

In at least one embodiment of the disclosure, the source-drain conductive layer further includes a coplanar waveguide, the in pad, the out pad, and at least one DC pad; the DC pad and the power supply device are the same in quantity and are electrically connected in a one-to-one correspondence; the coplanar waveguide includes a first portion and a second portion with a gap therebetween; the in pad and the out pad are located within the gap; and

orthographic projections of the transistor, the resistor, the in pad, the out pad and the DC pad on the glass substrate do not overlap with an orthographic projection of the coplanar waveguide on the glass substrate, respectively; and the coplanar waveguide is electrically connected to the ground terminal.

In at least one embodiment of the disclosure, in the case where the switch sub-circuit includes a first switch unit, the first portion of the coplanar waveguide includes a first hollowed-out region, and the second portion of the coplanar waveguide includes a second hollowed-out region; and

a portion of the first semiconductor pattern of the first transistor and a portion of the first electrode of the first transistor extend into the first hollowed-out region; a portion of the first semiconductor pattern, a portion of the first electrode of the first transistor, the first resistor, the DC pad, the first trace, the second trace, and the third trace are all located in the second hollowed-out region.

In at least one embodiment of the disclosure, in the case where the switch sub-circuit includes a second switch unit and a third switch unit, the first portion of the coplanar waveguide includes a third hollowed-out region, the second portion of the coplanar waveguide includes a fourth hollowed-out region and a fifth hollowed-out region which are connected; and

a portion of the first semiconductor pattern of the second transistor and a portion of the first electrode of the second transistor extend into the third hollowed-out region; the third transistor, the third resistor and the DC pad electrically connected to the third power supply device are all located in the fourth hollowed-out region; the second resistor and the DC pad electrically connected to the second power supply device are located in the fifth hollowed-out region.

In at least one embodiment of the disclosure, in the case where the switch sub-circuit includes a fourth switch unit, a fifth switch unit, a sixth switch unit, and a seventh switch unit, the first portion of the coplanar waveguide includes a sixth hollowed-out region and a seventh hollowed-out region, the second portion of the coplanar waveguide includes an eighth hollowed-out region and a ninth hollowed-out region, the sixth hollowed-out region is connected to the seventh hollowed-out region, and the eighth hollowed-out region is connected to the ninth hollowed-out region;

a body portion of the fifth transistor and a body portion of the sixth transistor are located within the gap; and

the fourth transistor and the fourth resistor are located in the eighth hollowed-out region; a portion of the first semiconductor pattern of the fifth transistor, a portion of the first electrode of the fifth transistor, the fifth resistor, and the DC pad electrically connected to the fifth power supply device are located in the sixth hollowed-out region; a portion of the first semiconductor pattern of the sixth transistor and a portion of the first electrode of the sixth transistor are located in the seventh hollowed-out region; a portion of the first semiconductor pattern of the sixth transistor, a portion of the first electrode of the sixth transistor, the sixth resistor, and the DC pad electrically connected to the sixth power supply device are located in the ninth hollowed-out region; and a body portion of the seventh transistor and the seventh resistor are located in the seventh hollowed-out region.

In a second aspect, the embodiment of the disclosure provides a radio frequency chip, including the switch structure described in the first aspect.

In a third aspect, the embodiment of the disclosure provides a method for preparing a switch structure, applied to prepare the switch structure described in the first aspect, wherein the method includes:
providing a glass substrate;
bonding a monocrystalline silicon thin film to the glass substrate;
patterning the monocrystalline silicon thin film to obtain a first semiconductor pattern and a second semiconductor pattern; and
performing ion implantation on a local region of the first semiconductor pattern and a local region of the second semiconductor pattern respectively, and performing annealing treatment on the first semiconductor pattern and the second semiconductor pattern at a predetermined temperature, so that the first semiconductor pattern and the second semiconductor pattern include a conducted region; an ion implantation dose of the conducted region ranges from 3×1015 cm-3 to 9×1015 cm-3, an ion doping concentration of the conducted region is greater than or equal to 1×1018 cm-3, and the predetermined temperature is less than 650° C.

The above description is only an overview of the technical solution of the present application. In order to have a clearer understanding of the technical means of the present application, it can be implemented according to the content of the specification. In order to make the above and other purposes, features, and advantages of the present application more obvious and easier to understand, the specific implementation methods of the present application are listed below.

### BRIEF DESCRIPTION OF THE DRAWINGS

In order to more clearly illustrate the technical solutions of the embodiments of the present application, the figures that are required to describe the embodiments of the present application will be briefly described below. Apparently, the figures that are described below are merely a part of the embodiments of the present application, and a person skilled in the art can obtain other figures according to these figures without paying creative work.

FIG. 1 shows a line graph of the change in resistivity of a monocrystalline silicon thin film bonded to a glass substrate with the change in ion implantation dose provided in an embodiment of the disclosure;

FIG. 2 shows a line graph of the change in impurity concentration of a monocrystalline silicon thin film bonded to a glass substrate with the change in ion implantation dose provided in an embodiment of the disclosure;

FIGS. 3, 11 and 12 are schematic diagrams of circuit structures of three switch sub-circuits provided in embodiments of the disclosure;

FIG. 4 is a schematic diagram of a planar structure of the circuit shown in FIG. 3;

FIGS. 5, 6 and 7 are schematic diagrams of planar structures of three transistors provided in embodiments of the disclosure;

FIGS. 8 and 10 are schematic diagrams of planar structures of gates of two transistors provided in embodiments of the disclosure;

FIG. 9 is a schematic diagram of a cross-sectional structure of a switch structure provided in an embodiment of the disclosure;

FIG. 13 is a schematic diagram of a planar structure of the circuit structure shown in FIG. 11;

FIG. 14 is a schematic diagram of a planar structure of two sub-transistors arranged in parallel;

FIG. 15 is a schematic diagram of a planar structure of the circuit structure shown in FIG. 12;

FIG. 16 is a schematic diagram of another planar structure of the circuit structure shown in FIG. 3; and

FIGS. 17A-17L are schematic diagrams of the intermediate structures during the preparation process of the switch structure provided in an embodiment of the disclosure.

### DETAILED DESCRIPTION OF THE EMBODIMENTS

The technical solutions according to the embodiments of the present application will be clearly and completely described below with reference to the drawings according to the embodiments of the present application. Apparently, the described embodiments are merely a part of the embodiments of the present application, rather than all of the embodiments. All of the other embodiments that a person skilled in the art obtains on the basis of the embodiments of the present application without paying creative work fall within the protection scope of the present application.

In the embodiments of the present disclosure, terms such as “first”, “second”, “third”, “fourth” are used to distinguish identical items or similar items that have substantially the same functions and effects, merely in order to clearly describe the technical solutions of the embodiments of the present disclosure, and should not be construed as indicating or implying the degrees of importance or implicitly indicating the quantity of the specified technical features.

In the embodiments of the present disclosure, an orientation or positional relationship indicated by terms “upper” and “lower” is based on an orientation or positional relationship shown in the drawings, and is merely for convenience of describing the present disclosure and simplifying the description, rather than indicates or implies that the device or element referred to must have a specific orientation, be configured and operated in a specific orientation, and thus cannot be understood as limitation on the present disclosure.

In the description of the present disclosure, the terms “one embodiment”, “some embodiments”, “exemplary embodiments”, “example”, “specific example” or “some examples” are intended to indicate that specific features, structures, materials or characteristics related to the embodiment or example are comprised in at least one embodiment or example of the present disclosure. The illustrative indication of the above terms does not necessarily refer to the same one embodiment or example. Moreover, the specific features, structures, materials or characteristics may be comprised in ally one or more embodiments or examples in any suitable manner.

In the embodiments of the present application, unless stated otherwise, the meaning of “plurality of” is “two or more”, and the meaning of “at least one” is “one or more”.

The terms “parallel”, “perpendicular” and “same” used in the embodiments of the present disclosure include the terms “parallel”, “perpendicular” and “same” in the strict sense, as well as the terms “substantially parallel”, “substantially perpendicular” and “substantially the same” which include certain tolerances. Considering the measurements and the tolerances associated with the measurements of a particular quantity (e.g., a limitation of the measurement system), they represent a range of acceptable deviations for a particular value as determined by a person of ordinary skill in the art. For example, “substantially” can mean within one or more standard deviations, or within 10% or 5% of the stated value.

Unless the context otherwise requires, in the entire specification and claims, the term “including” is interpreted as open and inclusive, meaning “including, but not limited to”.

The term “same layer” in the embodiments of the disclosure refers to the relationship between multiple film layers of the same material formed by the same step (such as a one-step patterning process). The term “same layer” here does not always refer to multiple film layers with the same thickness or that multiple film layers with the same height in a cross-sectional view. Polygons in this description are not strictly defined, but may be approximate triangles, parallelograms, trapezoids, pentagons, or hexagons, etc., with some small deformations caused by tolerances.

An RF switch can connect any one or more of multiple RF signals through control logic to achieve switching between different types of paths, including switching between receiving and transmitting, and switching between different frequency bands etc., so as to achieve the purpose of sharing an antenna and saving the cost of a terminal product. Currently, the commonly used RF switch technology is RF SOI (Radio Frequency Silicon On Insulator). RF switch products of SOG (Silicon On Glass) technology are rarely seen.

Based on this, the disclosure proposes a switch structure of SOG technology, which can achieve low-cost preparation of the switch structure. Further, SOG has better insulation performance than SOI, which can reduce the leakage of RF signals. In addition, in order to achieve impurity activation of monocrystalline silicon after ion implantation, since the heat resistance temperature of high-temperature glass is about 650° C. the existing high-temperature annealing process at 1000° C. cannot be achieved. Therefore, the disclosure also proposes a low-temperature process to achieve doping and impurity activation of monocrystalline silicon, in order to complete the preparation of the switch structure based on SOG technology.

Embodiments of the disclosure provides a switch structure and a preparation method thereof, and an RF chip. The switch structure includes a glass substrate; at least one switch sub-circuit located on the glass substrate and including at least one switch unit, where the switch unit includes a transistor, a resistor, and a power supply device, a gate of the transistor is electrically connected to the resistor, the resistor is electrically connected to the power supply device, a first electrode of at least one transistor is electrically connected to an in pad, and a second electrode of at least one transistor is electrically connected to an out pad; a silicon material layer located on and bonded to the glass substrate and including a conducted region, where a portion of the conducted region is configured to electrically connect the gate of the transistor and the resistor. An ion doping concentration of the conducted region is greater than or equal to 1×10¹⁸ cm⁻³. In the switch structure provided by embodiments of the disclosure, the silicon material layer is directly provided on the glass substrate, and the ion doping concentration in a local region of the silicon material layer is greater than or equal to 1×10¹⁸ cm⁻³. In this way, in the actual preparation process, after annealing the silicon material layer using a low-temperature process, it is possible to achieve the activation of impurities and the conduction of the local region of the silicon material layer. In addition, by directly bonding the silicon material layer to the glass substrate, it is possible to greatly reduce the leakage of the RF signal and improve the signal transmission stability of the switch structure compared with the switch structure of the SOI technology.

The switch structure and the preparation method thereof, and the RF chip provided by the embodiments of the disclosure will be specifically introduced and described below with reference to the accompanying drawings.

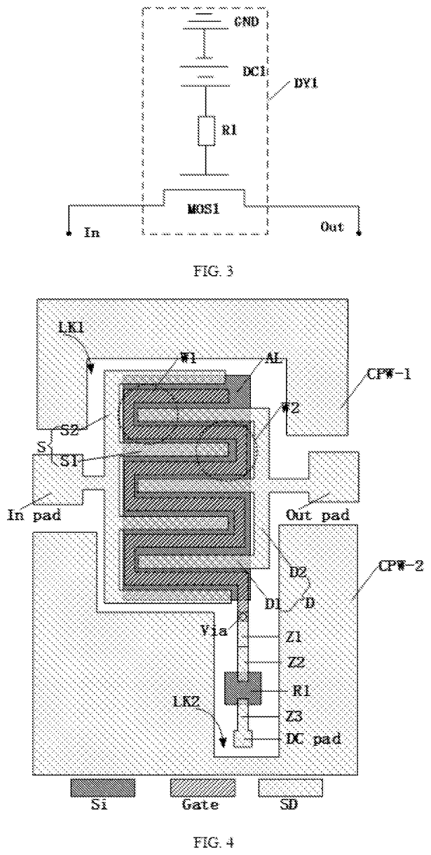

An embodiment of the disclosure provides a switch structure, as shown in FIGS. 3, 11, 12 and 9, including:
a glass substrate 100; and
at least one switch sub-circuit (three types of switch sub-circuits are respectively shown in FIGS. 3, 11 and 12) located on the glass substrate 100, where the switch sub-circuit includes at least one switch unit (for example, a first switch unit DY1 shown in FIG. 3, a second switch unit DY2 and a third switch unit DY3 shown in FIG. 11, a fourth switch unit DY4, a fifth switch unit DY5, a sixth switch unit DY6 and a seventh switch unit DY7 shown in FIG. 12).

In the case of the switch sub-circuit shown in FIG. 3, the switch unit includes a transistor (e.g., MOS1), a resistor (for example, R1) and a power supply device (not shown). A gate Gate of the transistor is electrically connected to the resistor (e.g., R1). The resistor (e.g., R1) is electrically connected to the power supply device. A first electrode of at least one transistor is electrically connected to an in pad (In pad), and a second electrode of at least one transistor is electrically connected to an out pad (Out pad).

As shown in FIG. 9, the switch structure further includes a silicon material layer 1 located on and bonded to the glass substrate 100. The silicon material layer 1 includes a conducted region, for example, the region marked A2. A portion of the conducted region is configured to electrically connect the gate of the transistor and the resistor, where an ion doping concentration of the conducted region is greater than or equal to 1×10¹⁸ cm⁻³.

Illustratively, the switch structure may include an RF switch.

The glass substrate 100 has better resistivity than other plastic or resin insulating substrates. Therefore, when applied in the RF switch, it can reduce the leakage of RF signal and improve the signal transmission stability.

The quantity of switch sub-circuits provided on the above glass substrate 100 is not limited herein.

In some examples, a switch sub-circuit may be provided on the glass substrate 100.

In some examples, a plurality of switch sub-circuits may be provided on the glass substrate 100, where the plurality refers to two or more.

Illustratively, a plurality of switch sub-circuits arranged in an array may be provided on the glass substrate 100.

Each switch sub-circuit includes at least one switch unit. For the same switch structure, each switch sub-circuit includes the same quantity of switch units, where the quantity of switch units included in the switch sub-circuit is related to the design of the switch sub-circuit, and is not limited herein.

In the embodiment of the disclosure, since the source and drain of the transistor are symmetrical, they are interchangeable. One of the “first electrode” and “second electrode” of the above transistor is the source and the other is the drain.

Illustratively, the above transistor is an MOS transistor, i.e., an Metal-Oxide-Semiconductor field effect transistor.

Illustratively, the above power supply device (e.g., a battery) may be built into the switch sub-circuit, or the above power supply device may be an external power supply.

There is no limitation on the type of the above power supply device.

In some examples, the power supply device may be a direct current (DC) device.

In some examples, the power supply device may be an alternating current (AC) device.

It should be noted that in the relevant circuit diagrams provided in the embodiments of the disclosure, the power supply device is marked and drawn as a direct current power supply. In addition, in the planar structure diagram of the switch structure provided in the embodiments of the disclosure, the power supply device is not drawn, and only conductive pads (or called conductive terminal) electrically connected to the power supply device, such as the structure labeled DC pad in FIG. 4, are drawn.

In the exemplary embodiment, the glass substrate 100 and the silicon material layer 1 are bonded together using a bonding process.

Illustratively, since the main component of glass is silica (SiO₂, i.e., quartz, the main component of sand). Since a melting point of pure silica is 2000° C., sodium carbonate (Na₂CO₃, i.e., soda) and potassium carbonate (Potash, K₂CO₃, potassium carbonate) are generally added when manufacturing glass, so that the melting point of silica decreases to about 1000° C.

In the actual bonding process, a negative voltage is applied to the glass substrate 100 and a positive voltage is applied to the silicon material layer 1. At a predetermined temperature and pressure, atoms near the interface between the glass substrate 100 and the silicon material layer 1 migrate and move to each other's film layer, thereby achieving the bonding of the glass substrate 100 and the silicon material layer 1. The difference between voltages applied on the glass substrate 100 and the silicon material layer 1 is about 200 V, and the predetermined temperature is 200° C.-400° C. The specific details of bonding can refer to the introduction of bonding process in the related art, which will not be elaborated herein.

In the exemplary embodiment, the main component of the silicon material layer 1 may be monocrystalline silicon.

Illustratively, when the main component of the silicon material layer 1 is monocrystalline silicon, the initial resistivity of the silicon material layer 1 before the ion implantation process and the annealing process is 10±2 Ω·cm.

In the embodiment of the disclosure, the silicon material layer 1 includes a conducted region. The impurities can be activated by a low temperature annealing process after ion doping, thereby achieving the conducting of the local region of the silicon material layer 1.

In the conventional SOI process, in order to achieve complete activation of monocrystalline silicon after ion implantation, the annealing temperature often reaches 1000° C. However, since the heat-resistance temperature of high-temperature glass is about 650° C., the conventional annealing temperature cannot be used. Therefore, it is necessary to find a low-temperature annealing process.

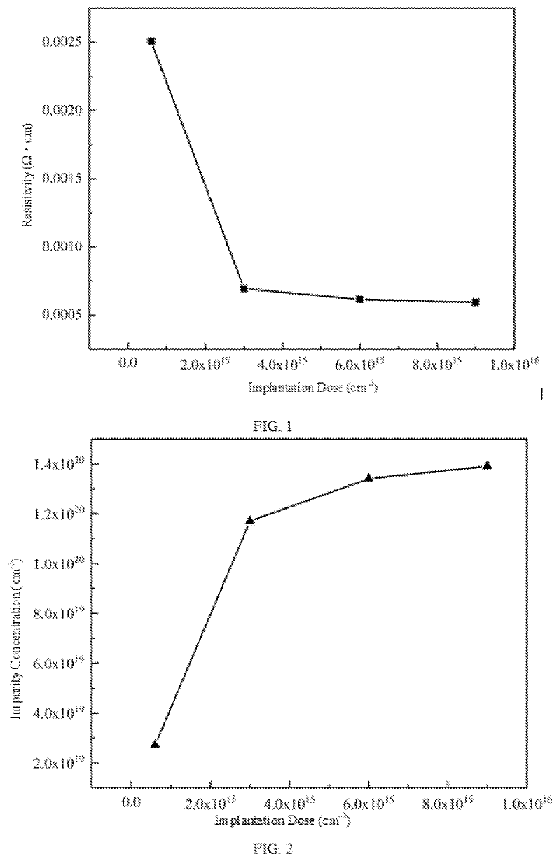

FIG. 1 provides a line graph of resistivity versus impurity concentration for the silicon material layer 1 with an initial resistivity of 10 Ω·cm and a main component of monocrystalline silicon after implantation of different doses of phosphorus ions and annealing at 600° C. for 1 h. It can be seen from FIG. 1 that when the implantation dose of phosphorus ions is 3×10¹⁵ cm⁻², the resistivity is less than 0.001 Ω·cm. In combination with FIG. 2, it can be seen that the concentration of phosphorus ion impurities can be greater than 1×10¹⁸ cm⁻³, which achieves heavy doping of silicon to meet the ohmic contact requirements between the metal and the semiconductor.

Illustratively, in practical applications, the concentration of phosphorus ion impurities may be set to be greater than 1×10²⁰ cm⁻³.

Ohmic contact means there is pure resistance at the contact between the metal and the semiconductor, and the smaller the resistance, the better, so that most of voltage drop during the operation of the device operation is in the active area rather than the contact surface. Therefore, its I-V characteristic is linear, and the larger the slope, the smaller the contact resistance. The size of the contact resistance directly affects the performance index of the device.

In the embodiment of the disclosure, the ion implantation dose for the silicon material layer 1 with the initial resistivity of 10 Ω·cm and the main component of monocrystalline silicon ranges from 3×10¹⁵ cm⁻³ to 9×10¹⁵ cm⁻³.

It should be noted that the conducting process is related to the solid-phase epitaxial growth process. When the implantation dose of phosphorus (P⁺) ions is greater than or equal to 6×10¹⁴ cm⁻², the surface of the monocrystalline silicon film layer becomes amorphous silicon, and the monocrystalline silicon underlying the amorphous silicon can be used as seed crystals for the recrystallization of amorphous silicon. In the annealing process, the amorphous silicon in the surface layer recrystallizes and grows into monocrystalline silicon. In the direction of <100> crystal plane, the rate of the recrystallization growth is 10 nm/min at a temperature of 550° C. and 50 nm/min at a temperature of 600° C. In this process, the dopant atoms enter the lattice positions with the main atoms, so that the dopant atoms are activated at a relatively low temperature.

Solid-phase epitaxy refers to a process of epitaxial recrystallization of an amorphous layer on a monocrystalline layer of a semiconductor at a temperature below the melting or eutectic point of the material.

In the switch structure provided by the embodiment of the disclosure, the silicon material layer 1 is directly provided on the glass substrate 100, and the ion doping concentration in the local region of the silicon material layer 1 is greater than or equal to 1×10¹⁸ cm⁻³. In this way, in the actual preparation process, after annealing the silicon material layer 1 using a low-temperature process, it is possible to achieve the activation of impurities and the conducting of the local region of the silicon material layer 1. In addition, by directly bonding the silicon material layer 1 to the glass substrate 100, it is possible to greatly reduce the leakage of the RF signal and improve the signal transmission stability of the switch structure compared with the switch structure of the SOI technology.

In at least one embodiment of the disclosure, at least one of the first electrode of the transistor, the second electrode of the transistor, and the gate of the transistor includes an interdigital structure.

Illustratively, the first electrode of the transistor includes an interdigital structure.

Illustratively, the second electrode of the transistor includes an interdigital structure.

Illustratively, the gate of the transistor includes an interdigital structure.

Illustratively, the first electrode, the second electrode, and the gate of the transistor each include an interdigital structure.

The quantity of interdigital included in the above interdigital structure is not limited herein, which may be determined based on the plane size of the interdigital and the performance requirements of the transistor.

In at least one embodiment of the disclosure, as shown in FIG. 5, the first electrode (e.g., a source S) of the transistor, the second electrode (e.g., a drain D) of the transistor, and the gate Gate of the transistor all include an interdigital structure. An orthographic projection of the gate Gate of the transistor on the glass substrate 100 partially overlaps with an orthographic projection of one of the first electrode of the transistor and the second electrode of the transistor on the glass substrate 100.

Illustratively, the first electrode of the transistor is a source S and the second electrode is a drain D. Alternatively, the first electrode of the transistor is a drain D and the second electrode is a source S.

Illustratively, since the first electrode (e.g., the source S) of the transistor, the second electrode (e.g., the drain D) of the transistor, and the gate Gate of the transistor all include an interdigital structure. It is inevitable that the orthographic projection of the gate Gate of the transistor partially overlaps with the orthographic projection of one of the first electrode and the second electrode of the transistor on the glass substrate 100, as shown in a region marked by a dashed circle in FIG. 5. The smaller the area of the overlap region, the smaller the parasitic capacitance between the gate Gate and the source (or the drain) of the transistor, the better the electrical performance of the transistor, and the more stable the control of the signal.

In some examples, as shown in FIG. 5, a width of the interdigital in a region marked by a dashed circle may be set smaller than a width of the interdigital in a region outside the dashed circle, thereby reducing the overlap area between the gate Gate and the source (or the drain) of the transistor, improving the electrical performance of the transistor, and improving the stability of the transistor.

Illustratively, a width of a portion of the gate Gate of the transistor located in a region marked by the dashed circle may be set smaller than a width of a portion of the gate of the transistor located in a region outside the dashed circle.

Illustratively, a width of a portion of the drain D of the transistor located in a region marked by the dashed circle may be set smaller than a width a portion of the gate of the transistor located in a region outside the dashed circle.

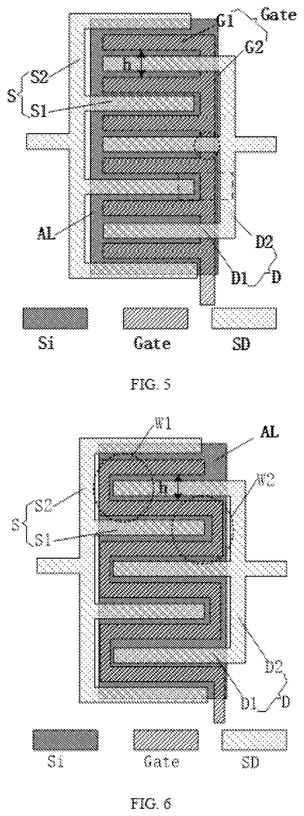

In at least one embodiment of the disclosure, as shown in FIG. 6 or FIG. 7, the first electrode (e.g., the source S) of the transistor and the second electrode (e.g., the drain D) of the transistor include an interdigital structure. The gate Gate of the transistor includes a serpentine structure.

The orthographic projection of the gate Gate of the transistor on the glass substrate 100 is located between the orthographic projection of the first electrode (e.g., the source S) of the transistor on the glass substrate 100 and the orthographic projection of the second electrode (e.g., the drain D) of the transistor on the glass substrate 100. The orthographic projections of the gate Gate of the transistor, the first electrode (e.g., the source S) of the transistor, and the second electrode (e.g., the drain D) of the transistor on the glass substrate 1 do not overlap each other.

In the embodiment of the disclosure, as shown in FIG. 6 or FIG. 7, the gate Gate of the transistor includes a serpentine structure, which can increase the switching ratio of the transistor. In addition, the orthographic projections of the gate Gate, the first electrode (e.g., the source S), and the second electrode (e.g., the drain D) of the transistor on the glass substrate 1 do not overlap each other, so that the parasitic capacitance between the gate Gate and the source S (or the drain D) can be reduced, and the performance of the switch device can be improved.

The switching ratio refers to the ratio between a turn-on state and a turn-off state of a switch in a circuit. In circuit design, the switching ratio is a very important parameter which directly affects the performance and stability of the circuit. In a circuit, the switching ratio is commonly used to describe the ratio between the turn-on time and the turn-off time of a switch transistor.

In at least one embodiment of the disclosure, a channel width-to-length ratio of the transistor is greater than or equal to 5000.

In practical applications, the on-resistance of a single transistor can be calculated from the following formula:

$${R}_{on} = \frac{1}{μ {C}_{ox} \frac{W}{L} ( {V}_{GS} - {V}_{th} )} ;$$

where μ is a carrier mobility; Cₒₓ is a capacitance between the gate of the transistor and the conducted region in the silicon material layer 1, the size of which is related to a thickness of the gate insulating layer; V_{GS} is a gate-source voltage; Vₜₕ is a threshold voltage of the transistor; W is a channel width of the transistor; and L is a channel length of the transistor.

Since the transistor (MOS transistor) requires a smaller on-resistance Rₒₙ for turning on, a larger channel width-to-length ratio is required. By setting W/L>5000 and setting the channel width of the transistor (MOS transistor) used in the switch structure to be in the range of 0.1 mm-10 mm, normal use of the switch structure can be achieved.

It should be noted that the channel width W, for the transistors shown in FIG. 5 or FIG. 6, can be significantly increased compared to a conventionally designed transistor.

where

$$Δ W = ( n - 1 ) \cdot {S}_{gate} ;$$

As shown in FIGS. 5 and 6, n is a quantity of the interdigitals of the gate Gate, and S_{gate} is a distance h between two interdigitals of the gate. In the case of the structure shown in FIG. 5, n is 6. In the case of the structure shown in FIG. 6, n is 6. For the gate Gate with a serpentine structure as shown in FIG. 6, the quantity of the interdigitals n refers to a quantity of line segments extending in the horizontal direction in the serpentine gate.

In addition, for the gate of the serpentine structure as shown in FIG. 6, since there is no overlap between the gate Gate and the source S (or the drain D), the magnitude of the parasitic capacitance of the transistor that can be reduced is as follows:

$$Δ C = {ε}_{ILD} \frac{{nW}_{SD} \cdot {W}_{gate}}{2 {d}_{ILD}} ,$$

where ε_{ILD} is a dielectric constant of the inter level dielectric layer (an insulating layer located between the gate Gate and the source S), W_{SD} is a width of the source/drain, W_{gate} is a width of the gate, and d_{ILD} is a thickness of the inter level dielectric layer.

It should be noted that the conducting process described above is related to the solid phase epitaxial growth process. When the implantation dose of phosphorus (P⁺) ions is greater than or equal to 6×10¹⁴ cm⁻², the surface of the monocrystalline silicon film layer becomes amorphous silicon, and the monocrystalline silicon underlying the amorphous silicon can be used as the seed crystal for amorphous silicon recrystallization. In the annealing process, the amorphous silicon in the surface layer recrystallizes and grows into monocrystalline silicon.

In at least one embodiment of the disclosure, the surface of the monocrystalline silicon film layer becomes amorphous silicon, which can be fully recrystallized, so that the silicon material layer 1 includes a monocrystalline silicon sub-layer.

In at least one embodiment of the disclosure, the surface of the monocrystalline silicon film layer becomes amorphous silicon, which can be recrystallized, but a small amount of amorphous silicon still exists in the surface layer. At this time, the silicon material layer 1 includes a monocrystalline silicon sub-layer and an amorphous silicon sub-layer successively arranged on the glass substrate 100. A thickness of the amorphous silicon sub-layer is less than a thickness of the monocrystalline silicon sub-layer.

The specific structure of the switch sub-circuit is described and explained below.

In at least one embodiment of the disclosure, as shown in FIGS. 3 and 4, the switch sub-circuit includes an in pad and an out pad.

An in pad corresponds to an input port, and an out pad corresponds to an output port.

In at least one embodiment of the disclosure, as shown in FIG. 3, the switch sub-circuit includes a first switch unit DY1. The first switch unit DY1 includes a first transistor MOS1 and a first resistor R1. The power supply device includes a first power supply device DC1.

A first electrode (e.g., a source S) of the first transistor MOS1 is electrically connected to the in pad, and a second electrode (e.g., a drain D) of the first transistor MOS1 is electrically connected to the out pad. A gate Gate of the first transistor MOS1 is electrically connected to a first terminal of the first resistor R1. The first power supply device DC1 is electrically connected to the ground terminal GND and a second terminal of the first resistor R1, respectively.

FIG. 3 shows a switch structure of a single-pole-single-throw structure. When the first transistor MOS1 is turned on, the switch sub-circuit is equivalent to a resistor with a very low resistance value, the RF signal can be passed through the switch sub-circuit. When the first transistor MOS1 is turned off, the switch sub-circuit is equivalent to a capacitor, which can prevent the RF signal from passing therethrough, and achieving the cut-off of the switch structure. The gate Gate of the first transistor MOS1 is connected to the first resistor R1, which can effectively prevent the breakdown between the gate Gate and the drain D or between the gate Gate and the source S when the peak-to-peak value of the RF signal on the source and the drain is too large.

The resistance value of the first resistor R1 ranges from 10 kΩ to 100 KΩ, for example, 20 kΩ, 30 kΩ, 40 kΩ, 50 kΩ, 60 kΩ, 70 kΩ, 80 kΩ, and 90 kΩ.

In at least one embodiment of the disclosure, as shown in FIG. 11, the switch sub-circuit includes a second switch unit DY2 and a third switch unit DY3. The second switch unit DY2 includes a second transistor MOS2 and a second resistor R2. The third switch unit DY3 includes a third transistor MOS3 and a third resistor R3. The power supply device includes a second power supply device DC2 and a third power supply device DC3.

A first electrode (e.g., a source S) of the second transistor MOS2 and a first electrode (e.g., a source S) of the third transistor MOS3 are electrically connected to the in pad. A second electrode (e.g., a drain D) of the second transistor MOS2 is electrically connected to the out pad, a gate Gate of the second transistor MOS2 is electrically connected to a first terminal of the second resistor R2, and the second power supply device DC2 is respectively electrically connected to the ground terminal GND and a second terminal of the second resistor R2.

A gate Gate of the third transistor MOS is electrically connected to a first terminal of the third resistor R3. The third power supply device DC3 is electrically connected to the ground terminal GND and a second terminal of the third resistor R3, respectively. A second electrode (e.g., a drain D) of the third transistor MOS3 is electrically connected to the ground terminal GND.

Illustratively, the second resistor R2 and the third resistor R3 each have a resistance value ranging from 10 kΩ to 100 KΩ.

There is no limitation on whether the structure, size, and electrical parameters of the second transistor MOS2 and the third transistor MOS3 described above are the same.

Illustratively, when the structure, size, and electrical parameters of the second transistor MOS2 and the third transistor MOS3 are the same, the second resistor R2 and the third resistor R3 have the same resistance value, and the second power supply device DC2 and the third power supply device DC3 provide the same power supply voltage.

On the basis of switch structure of the single-pole-single-throw structure shown in FIG. 3, a series branch can be added to increase the isolation of the switch structure. The isolation, i.e. the attenuation between the input port and the output port of the circuit, is a measure of the effectiveness of the switch cutoff.

FIG. 11 provides a circuit structure of a switch structure of a single-pole-single-throw series-parallel structure. The second switch unit DY2 is a series branch, and the third switch unit DY3 is a parallel branch, and each branch includes a resistor electrically connected to a gate of the transistor. When a positive voltage is applied on the gate Gate of the second transistor MOS2 in the series branch, and a negative voltage is applied on the gate Gate of the third transistor MOS3 in the parallel branch, the series branch is turned on, and the parallel branch is turned off, the RF signal is output through the series branch, and the switch is in an on-state. When a negative voltage is applied on the gate Gate of the second transistor MOS2 in the series branch, and a positive voltage is applied on the gate Gate of the third transistor MOS3 in the parallel branch, the series branch is tuned off, and the parallel branch is turned on, the RF signal flows into the ground terminal GND through the parallel branch, and the switch is in an off-state. Compared to the switch structure in FIG. 3, a grounded parallel branch is added in the switch structure shown in FIG. 1 in the off-state, which improves the isolation of the switch structure.

In at least one embodiment of the disclosure, as shown in FIG. 12, the switch sub-circuit includes a fourth switch unit DY4, a fifth switch unit DY5, a sixth switch unit DY6 and a seventh switch unit DY7.

The fourth switch unit DY4 includes a fourth transistor MOS4 and a fourth resistor R4. The fifth switch unit DY5 includes a fifth transistor MOS5 and a fifth resistor R5. The sixth switch unit DY6 includes a sixth transistor MOS6 and a sixth resistor R6. The seventh switch unit DY7 includes a seventh transistor MOS7 and a seventh resistor R7. The power supply device includes a fifth power supply device DC5 and a sixth power supply device DC6.

The fourth switch unit DY4 and the sixth switch unit DY6 share the sixth power supply device DC6. The fifth switch unit DY5 and the seventh switch unit DY7 share the fifth power supply device DC5.

In at least one embodiment of the disclosure, as shown in FIG. 12, the switch sub-circuit includes one in pad and two out pads. One in pad corresponds to one input port and two out pads correspond to two output ports.

In at least one embodiment of the disclosure, the switch sub-circuit includes two in pads and one out pad. Two in pads correspond to two input ports, and one out pad corresponds to one output port.

In at least one embodiment of the disclosure, as shown in FIG. 12, first electrodes (e.g., sources S) of the fourth transistor MOS4 and the fifth transistor MOS5 are electrically connected to a first out pad (a conductive pad electrically connected to an output port on the left side in FIG. 12). A second electrode (e.g., a drain D) of the fourth transistor MOS4 is electrically connected to the ground terminal GND. A second electrode (e.g., a drain D) of the fifth transistor MOS5 is electrically connected to an in pad. A gate Gate of the fourth transistor MOS4 is electrically connected to a first terminal of the fourth resistor R4. A gate Gate of the fifth transistor MOS5 is electrically connected to a first terminal of the fifth resistor R5.

First electrodes (e.g., sources S) of the sixth transistor MOS6 and the seventh transistor MOS7 are electrically connected to a second out pad (a conductive pad electrically connected to an output port on the right side in FIG. 12). A second electrode (e.g., a drain D) of the sixth transistor MOS6 is electrically connected to an in pad. A second electrode (e.g., a drain D) of the seventh transistor MOS7 is electrically connected to the ground terminal GND. A gate Gate of the sixth transistor MOS6 is electrically connected to a first terminal of the sixth resistor R6. A gate Gate of the seventh transistor MOS7 is electrically connected to a first terminal of the seventh resistor R7.

In at least one embodiment of the disclosure, as shown in FIG. 12, a second terminal of the fourth resistor R4 and a second terminal of the sixth resistor R6 are electrically connected to the sixth power supply device DC6, and a second terminal of the fifth resistor R5 and a second terminal of the seventh resistor D7 are electrically connected to the fifth power supply device DC5.

FIG. 12 provides a circuit structure of a single-pole-double-throw switch structure. The circuit structure of the switch structure may be divided into two channels, i.e., a channel L1 on the left side of the dashed line and a channel L2 on the right side of the dashed line in FIG. 12, where each of the channels includes a series branch and a parallel branch.

The series branch in the channel L1 is a fifth switch unit DY5, and the parallel branch is a fourth switch unit DY4. The series branch in the channel L2 is a sixth switch unit DY6, and the parallel branch is a seventh switch unit DY7. The fifth switch unit DY5 of the series branch in the channel L1 and the seventh switch unit DY7 of the parallel branch in the channel L2 share a direct current power supply (i.e., the gate Gate of the fifth transistor MOS5 and the gate Gate of the seventh transistor MOS7 are connected to the same direct current power supply). The fourth switch unit DY4 of the parallel branch in the channel L1 and the sixth switch unit DY6 of the series branch in the channel L2 share a direct current power supply (i.e., the gate Gate of the fourth transistor MOS4 and the gate Gate of the sixth transistor MOS6 are connected to the same direct current power supply). When the same positive voltage is applied to the gate Gate of the fifth transistor MOS5 and the gate Gate of the seventh transistor MOS7, and the same negative voltage is applied to the gate Gate of the fourth transistor MOS4 and the gate Gate of the sixth transistor MOS6, the channel L1 is turned on, the channel L2 is turned off, and the RF signals leaked from the output port of the channel L1 (such as the output port Out on the left side in FIG. 12) to the input port of the channel L2 is short-circuited to the ground terminal GND through the parallel branch in the channel L2, thereby significantly improving the isolation between the ports.

In at least one embodiment of the disclosure, the switch structure includes a plurality of switch sub-circuits arranged in an array on the glass substrate 100, thereby achieving the large-area integration of the switch device, expanding the application field of the switch structure, improving the application flexibility of the switch structure, and reducing the preparation cost of the switch structure.

In at least one embodiment of the disclosure, as shown in FIG. 14, the transistor includes a plurality of sub-transistors arranged in series (two sub-transistors arranged in series are drawn as an example in FIG. 14). As shown in FIG. 16, the gate Gate of each sub-transistor is connected to a resistor R. A first electrode (e.g., a source S) of the sub-transistor and a second electrode (e.g., a drain D) of the sub-transistor include an interdigital structure, and the gate Gate of the sub-transistor includes a serpentine structure.

FIG. 16 corresponds to a schematic diagram of a planar structure when the first transistor MOS1 in the switch sub-circuit as shown in FIG. 3 includes four sub-transistors.

In practical applications, the operating voltage and breakdown voltages of a single MOS transistor are relatively low and may not meet the requirements. The power processing capability of the switch structure is improved by connecting multiple low-voltage devices in series, so as to ensure that the switch structure can withstand enough high power signals. The greater the quantity of sub-transistors arranged in series, the lower the voltage actually applied to each MOS transistor.

In at least one embodiment of the disclosure, as shown in FIG. 9, the switch structure includes:
a silicon material layer 1 including a first semiconductor pattern 11 (AL) and a second semiconductor pattern 12;
a gate insulating layer 2 covering the silicon material layer 1;
a gate layer 3 located on a side of the gate insulating layer 2 away from the glass substrate 10 and including a gate Gate of a transistor;
an inter level dielectric layer 4 covering the gate layer 3; and
a source-drain conductive layer 5 located on a side of the inter level dielectric layer 4 away from the glass substrate 100, and including a first electrode (e.g., a source S) and a second electrode (e.g., a drain D) of the transistor.

The first semiconductor pattern 11 (AL) and the second semiconductor pattern 12 include a semiconductor region A1 and a conducted region A2 located on two sides of the semiconductor region A1. A first electrode (e.g., a source S) of the transistor is electrically connected to one conducted region A2 in the first semiconductor pattern 11 (AL). A second electrode (e.g., a drain D) of the transistor is electrically connected to the other conducted region A2 in the first semiconductor pattern 11 (AL). The semiconductor region A1 in the first semiconductor pattern 11 (AL) serves as a channel region of the transistor. The semiconductor region A1 in the second semiconductor pattern 12 serves as a resistor.

Illustratively, the main component of the above silicon material layer 1 is monocrystalline silicon. In some examples, the silicon material layer 1 includes monocrystalline silicon in the bottom layer and amorphous silicon in the top layer. In addition, the silicon material layer 1 also includes doping elements, for example, phosphorus atoms or boron atoms.

In an exemplary embodiment, the monocrystalline silicon in the silicon material layer 1 is mainly P-type silicon. In this case, the doping element in the conducted regions A2 in the first semiconductor pattern 11 (AL) is a phosphorus atom.

It should be noted that in this description, the transistor (MOS transistor) as an N-type MOS is taken as an example to illustrate.

In an exemplary embodiment, the doping element in the conducted region A2 in the second semiconductor pattern 12 may be a phosphorus atom or a boron atom.

In an exemplary embodiment, the material of the gate insulating layer 2 may be an inorganic material, such as silicon nitride (SiNx), silicon oxide (SiO₂), or silicon oxynitride (SiNxOy).

In an exemplary embodiment, the material of the gate layer 3 may be a metal, for example, a combination of one or more of copper (Cu), aluminum (Al), titanium (Ti), molybdenum (Mo).

In an exemplary embodiment, the material of the inter level dielectric layer (ILD) may be an organic material, such as a resin.

In an exemplary embodiment, the material of the inter level dielectric layer (ILD) may be an inorganic material, such as silicon nitride (SiNx), silicon oxide (SiO₂), or silicon oxynitride (SiNxOy).

In at least one embodiment of the disclosure, the source-drain conductive layer 5 further includes a first trace Z1, a second trace Z2, and a third trace Z3. The first trace Z1 is electrically connected to one of the second trace Z2 and the third trace Z3.

The first trace Z1 is electrically connected to the gate Gate of the transistor, the second trace Z2 is electrically connected to one of the conducted regions A2 in the second semiconductor pattern 12, and the third trace Z3 is electrically connected to the other of the conducted regions A2 in the second semiconductor pattern 12.

The second trace Z2 is electrically connected to one of the conducted regions A2 in the second semiconductor pattern 12 to serve as an input terminal of the resistor, and the third trace Z3 is electrically connected to the other of the conducted regions A2 in the second semiconductor pattern 12 to serve as an output terminal of the resistor; or, the second trace Z2 is electrically connected to one of the conducted regions A2 in the second semiconductor pattern 12 to serve as an output terminal of the resistor, and the third trace Z3 is electrically connected to the other of the conducted regions A2 in the second semiconductor pattern 12 to serve as an input terminal of the resistor, thereby realizing that one terminal of the resistor can be electrically connected to the gate Gate of the transistor and the other terminal of the resistor to be electrically connected to the power supply device.

In at least one embodiment of the disclosure, as shown in FIG. 5 or FIG. 6, for at least one transistor, a first electrode (e.g., a source S) of the transistor includes an interdigital structure. The first electrode (e.g., the source S) of the transistor includes a first connection portion S2 and N-2 first extension portions S1 arranged in the same row. The extension direction of the first connection portion S2 intersects with the extension direction of the first extension portions S1, and the arrangement direction of the first extension portions S1 is the same as the extension direction of the first connection portion S2. The first connection portion is located on the same side of each of the first extension portions and connects each of the first extension portions S1 together. N is a positive integer and is greater than or equal to 4.

The orthographic projection of each of the first extension portions S1 on the glass substrate 100 at least partially overlaps with the orthographic projection of the first semiconductor pattern 11 (AL) (the area marked with Si in FIG. 5 or FIG. 6) on the glass substrate, respectively.

“At least partially overlapping” includes partially overlapping and completely overlapping, which are described hereafter in a similar sense and will not be repeated here.

In an exemplary embodiment, one of the conducted regions A2 in the first semiconductor pattern 11 (AL) may be electrically connected to at least one first extension portion S1 in the first electrode of the transistor through a via hole.

In some examples, in order to reduce the contact resistance, one of the conducted regions A2 in the first semiconductor pattern 11 (AL) may be set to be electrically connected to a first extension portion S1 in the first electrode (e.g., the source S) of the transistor through two via holes, e.g., one via hole electrically connected to one of the first extension portions S1, and the other via hole electrically connected to the other of the first extension portions S1.

The shape of the planar pattern of the above first extension portions S1 is not limited herein. Illustratively, the shape of the planar pattern of the first extension portion S1 may be set to include two side edges that are parallel to each other, so that the distance between any two points on two adjacent first extension portions S1 is equal in the extension direction of the first connection portion S2. That is, the two side edges adjacent to each other on the two adjacent first extension portions S1 are arranged in parallel.

The length and the width of the above first extension portion S1 is limited herein. The length refers to a dimension of the first extension portion S1 in the extension direction thereof, and the width refers to a dimension of the first extension portion S1 in the extension direction of the first connection portion S2.

In an exemplary embodiment, the widths of the first extension portion S1 and the first connection portion S2 can be set to be substantially equal.

In some embodiments, an orthographic projection of the first semiconductor pattern 11 (AL) on the glass substrate 100 and an orthographic projection of the first connection portion S2 on the glass substrate 100 may be arranged to partially overlap.

In an exemplary embodiment, each of the first electrodes (e.g., the source S) of all transistors in the switch structure may be set to include an interdigital structure.

In at least one embodiment of the disclosure, as shown in FIG. 5 or FIG. 6, for at least one transistor, the second electrode (e.g., the drain) of the transistor includes an interdigital structure. The second electrode (e.g., the drain) of the transistor includes a second connection portion D2 and N-3 second extension portions D1 arranged in the same row. The extension direction of the second connection portion D2 is the same as the extension direction of the first connection portions S2, and the arrangement direction of the second extension portions D1 is the same as the arrangement direction of the first extension portions S1. The second connection portion D2 is located on the same side of each of the second extension portions D1 and connects each of the second extension portions D1 together.

The orthographic projection of each of the second extension portions D1 on the glass substrate 100 at least partially overlaps with the orthographic projection of the first semiconductor pattern 11 (AL) (the area marked with Si in FIG. 5 or FIG. 6) on the glass substrate 100, respectively.

In some embodiments, the length and the width of the first extension portion S1 and the second extension portion D1 may be set to be substantially equal.

In an exemplary embodiment, one of the conducted regions A2 in the first semiconductor pattern 11 (AL) may be electrically connected to at least one of the second extension portions D1 in the second electrode of the transistor through a via hole.

In some examples, in order to reduce the contact resistance, one of the conducted regions A2 in the first semiconductor pattern 11 (AL) may be set to be electrically connected to the second extension portion D1 in a second electrode (e.g., the drain D) of the transistor through two via holes, e.g., one via hole electrically connected to one of the second extension portions D1 and the other via hole electrically connected to the other of the second extension portions D1.

In an exemplary embodiment, widths of the second extension portion D1 and the second connection portion D2 can be set to be substantially equal.

In some embodiments, the orthographic projection of the first semiconductor pattern 11 (AL) on the glass substrate 100 and the orthographic projection of the second connection portion D2 on the glass substrate 100 can be arranged to partially overlap.

In an exemplary embodiment, the second electrodes (e.g., drain D) of all transistors in the switch structure can be provided to include an interdigital structure.

In at least one embodiment of the disclosure, as shown in FIG. 5, for at least one transistor, the gate Gate of the transistor includes an interdigital structure.

The gate Gate of the transistor includes a third connection portion G2 and N third extension portions G1 arranged in the same row. The extension direction of the third connection portion G2 intersects the extension direction of the third extension portions G1. The third connection portion G2 is located on the same side of each of the third extension portions G1 and connects each of the third extension portions G1 together. The orthographic projection of each of the third extension portions G1 on the glass substrate 100 at least partially overlaps with the orthographic projection of the first semiconductor pattern 11 (AL) on the glass substrate 100, respectively. In the case of an area marked by a dashed circle in FIG. 5, the orthographic projection of the third connection portion G2 partially overlaps with orthographic projections of all the second extension portions D1 on the glass substrate 100.

The orthographic projections of the first extension portions S1, the third extension portions G1, the second extension portions D1 on the glass substrate 100 are alternately arranged in sequence along the extension direction of the third connection portion G2.

In an exemplary embodiment, a length of the third extension portion G1 is less than a length of the first extension portion S1 and the second extension portion D1.

In an exemplary embodiment, in order to simplify the design and reduce the difficulty of the preparation process, the widths of the first extension portion S1, the third extension portion G1, and the second extension portion D1 can be set to be approximately equal.

In the planar pattern as shown in FIG. 5, any one of the third extension portions G1 is located between the first extension portion S1 and the second extension portion D1, and can be arranged in a plane parallel to the glass substrate 100, in order to improve the electrical property of the transistor and ensure that the voltage of the gate Gate is the same as the magnitude of the transverse parasitic capacitance generated between the first electrode (e.g., the source S) and the second electrode (e.g., the drain D) respectively. The distance between the third extension portion G1 and the adjacent first extension portion S1 is approximately equal to the distance between the third extension portion G1 and the adjacent second extension portion D1. That is, the third extension portion G1 is located at a middle position between the first extension portion S1 and the second extension portion D1.

In addition, in some embodiments, as shown in FIG. 5, a portion of the third connection portion G2 (e.g., an area marked by a rectangular dashed box in FIG. 5) is located between the first extension portion S1 and the second connection portion D2. For this portion of the third connection portion G2, a distance between the portion of the third connection portion G2 of the gate Gate and the first extension portion S1 and a distance between the portion of the third connection portion G2 and the second connection portion D2 can be set to be approximately equal in the extension direction of the first extension portions S1.

In at least one embodiment of the disclosure, in order to reduce the parasitic capacitance between the gate Gate and the source S (or drain D) of the transistor, for at least one transistor, as shown in FIGS. 6 and 7, the gate of the transistor includes a serpentine structure.

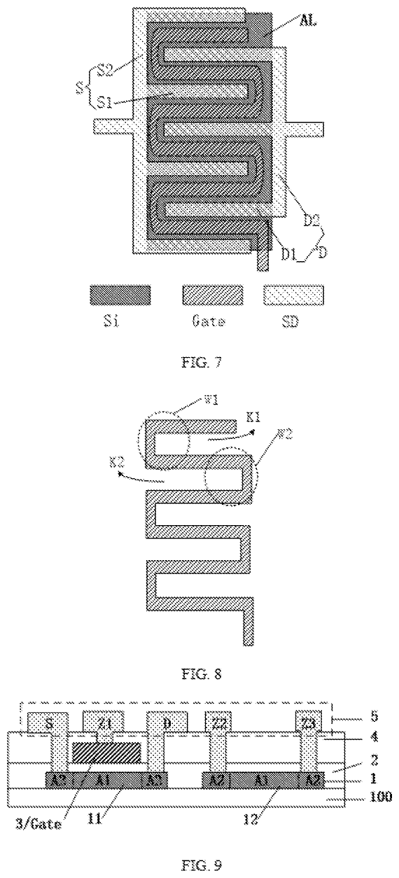

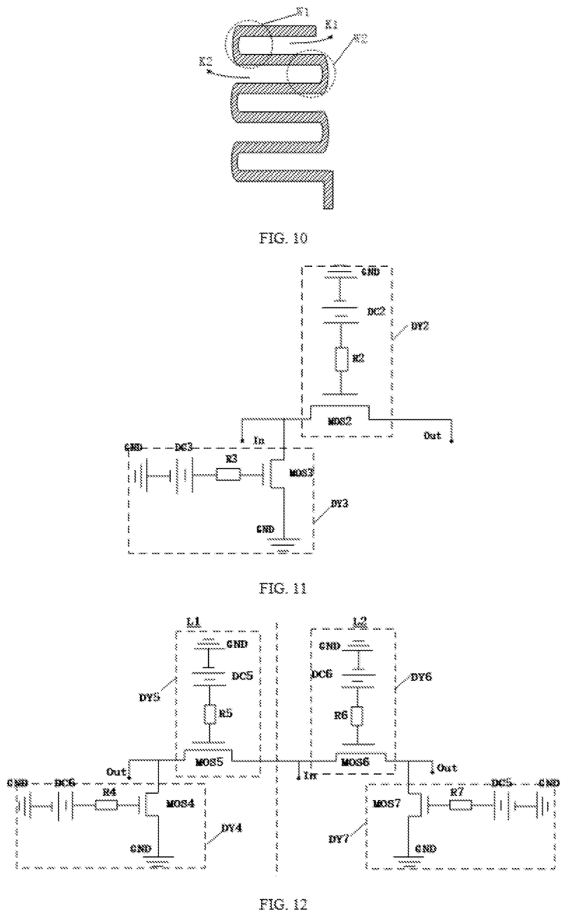

Illustratively, as shown in FIG. 8 or FIG. 10, the gate Gate of the transistor has a first bent portion W1 and a second bent portion W2 alternately arranged. The gate Gate of the transistor also has a first opening portion K1 and a second opening portion K2 alternately arranged, so that the gate Gate of the transistor has a serpentine structure. The outer contour of the first opening portion K1 is arranged on the first bent portion W1, the outer contour of the second opening portion K2 is arranged on the second bent portion W2, and the openings of the first opening portion K1 and the second opening portion K2 face opposite directions.

The orthographic projection of the gate Gate of the transistor on the glass substrate 100 does not overlap with the orthographic projection of the first electrode (e.g., the source S) of the transistor on the glass substrate 100, and the orthographic projection of the gate Gate of the transistor on the glass substrate 100 does not overlap with the orthographic projection of the second electrode (e.g., the drain D) of the transistor on the glass substrate 100.

Further, as shown in FIG. 8 or FIG. 10, the outer contour of the first opening portion K1 and the outer contour of the second opening portion K2 each include a combination of a plurality of straight line segments, a combination of a straight line segment and an arc, or an arc.

Illustratively, as shown in FIG. 8, the outer contour of the first opening portion K1 and the outer contour of the second opening portion K2 each include a combination of a plurality of straight line segments. For example, the outer contour of the first opening portion K1 and the outer contour of the second opening portion K2 each include a right angle structure.

Illustratively, as shown in FIG. 10, the outer contour of the first opening portion K1 and the outer contour of the second opening portion K2 each include a combination of a straight line segment and an arc. For example, the outer contour of the first opening portion K1 and the outer contour of the second opening portion K2 each include a rounded corner structure.

Illustratively, the outer contour of the first opening portion K1 and the outer contour of the second opening portion K2 each include an arc. For example, the outer contour of the serpentine structure is all an arc.

In some examples, at least one of interdigital structures of the first electrode (e.g., the source S) and second electrode (e.g., the drain D) of the transistor may be provided to include a rounded corner structure.

In at least one embodiment of the disclosure, as shown in FIG. 8 or FIG. 10, an outer contour of a side of the first bent portion W1 on which the first opening portion K1 is not provided and an outer contour of the side of the second bent portion W2 on which the second opening portion K2 is not provided include a combination of a plurality of straight line segments, a combination of a straight line segment and an arc, or an arc.

Illustratively, as shown in FIG. 8, the outer contour of the side of the first bent portion W1 on which the first opening portion K1 is not provided and the outer contour of the side of the second bent portion W2 on which the second opening portion K2 is not provided include a combination of a plurality of straight line segments. For example, the outer contour of the side of the first bent portion W1 on which the first opening portion K1 is not provided and the outer contour of the side of the second bent portion W2 on which the second opening portion K2 is not provided include a right angle structure.

Illustratively, as shown in FIG. 10, the outer contour of the side of the first bent portion W1 on which the first opening portion K1 is not provided and the outer contour of the side of the second bent portion W2 on which the second opening portion K2 is not provided include a combination of a straight line segment and an arc. For example, the outer contour of the side of the first bent portion W1 on which the first opening portion K1 is not provided and the outer contour of the side of the second bent portion W2 on which the second opening portion K2 is not provided include a rounded corner structure.

Illustratively, the outer contour of the side of the first bent portion W1 on which the first opening portion K1 is not provided and the outer contour of the side of the second bent portion W2 on which the second opening portion K2 is not provided include an arc. For example, the outer contour of the serpentine structure is all an arc.

In at least one embodiment of the disclosure, as shown in FIGS. 4, 13 and 15, the source-drain conductive layer (SD) further includes a coplanar waveguide (CPW) (including CPW-1 and CPW-2), an in pad, an out pad and at least one DC pad. The DC pad and the power supply device (not shown) are the same in quantity and are electrically connected in a one-to-one correspondence. The coplanar waveguide includes a first portion (CPW-1) and a second portion (CPW-2), and has a gap between the first portion (CPW-1) and the second portion (CPW-2) of the coplanar waveguide. The in pad and the out pad are located in the gap.

As shown in FIGS. 4, 13 and 15, the orthographic projections of all transistors, resistors, in pads, out pads and DC pads on the glass substrate 100 respectively do not overlap with the orthographic projection of the coplanar waveguide CPW (including CPW-1 and CPW-2) on the glass substrate 100, respectively. The coplanar waveguide CPW (including CPW-1 and CPW-2) are electrically connected to the ground terminal GND.

An in pad corresponds to an input port In, and an out pad corresponds to an output port Out.

The size and planar shape of the gap between the first portion CPW-1 and the second portion CPW-2 of the coplanar waveguide are not limited herein, and can be determined according to the design space.

In some examples, as shown in FIG. 4, at least a portion of the transistor is also located in the gap between the first portion CPW-1 and the second portion CPW-2 of the coplanar waveguide.

In at least one embodiment of the disclosure, as shown in FIG. 4, in the case where the switch sub-circuit includes a first switch unit DY1, a first portion CPW-1 of the coplanar waveguide includes a first hollowed-out region LK1, and a second portion CPW-2 of the coplanar waveguide includes a second hollowed-out region LK2.

A portion of a first semiconductor pattern 11 (AL) of the first transistor MOS1 (a region where the pattern marked with S1 is located in FIG. 4) and a portion of a first electrode (for example, the source S) of the first transistor MOS1 extend to the first hollowed-out region LK1. A portion of the first semiconductor pattern 11 (AL) (a region where the pattern marked with Si is located in FIG. 4), a portion of the first electrode (for example, the source S) of the first transistor MOS1, the first resistor R1, the DC pad, the first trace Z1, the second trace Z2, and the third trace Z3 are all located in the second hollowed-out region LK2.

In some examples, as shown in FIG. 4, a portion of the second electrode (e.g., the drain D) of the first transistor MOS1 extends to the first hollowed-out region LK1.

In some examples, as shown in FIG. 4, a portion of the second electrode (e.g., drain D) of the first transistor MOS1 extends to the second hollowed-out region LK2.

The shape and size of the planar patterns of the first hollowed-out region LK1 and the second hollowed-out region LK2 are not limited herein.

Illustratively, as shown in FIG. 4, the planar pattern of the first hollowed-out region LK1 is rectangular.

Illustratively, as shown in FIG. 4, the planar pattern of the second hollowed-out region LK2 is a spliced pattern formed by two rectangles.

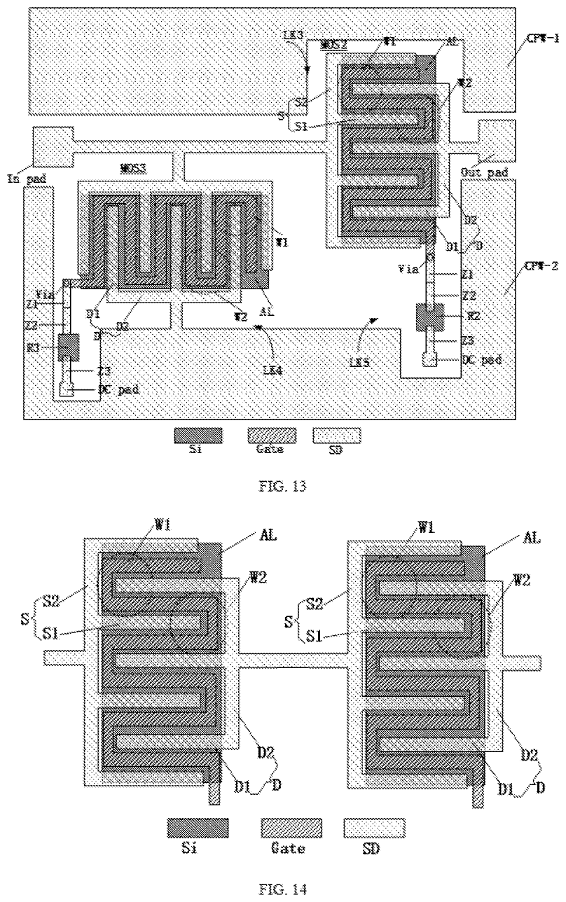

In at least one embodiment of the disclosure, in the case where the switch sub-circuit includes a second switch unit DY2 and a third switch unit DY3, as shown in FIG. 13, the first portion CPW-1 of the coplanar waveguide includes a third hollowed-out region LK3, and the second portion CPW-2 of the coplanar waveguide includes a fourth hollowed-out region LK4 and a fifth hollowed-out region LK5 which are connected. A portion of the first semiconductor pattern 11 (AL) of the second transistor MOS2 and a portion of a first electrode (for example, the source S) of the second transistor MOS2 extend to the third hollowed-out region LK3. The third transistor MOS3, the third resistor R3, and a DC pad electrically connected to the third power supply device DC3 are all located in the fourth hollowed-out region LK4. The second resistor R2 and a DC pad electrically connected to the second power supply device DC2 are located in the fifth hollowed-out region LK5.

In an exemplary embodiment, as shown in FIG. 13, a portion of the second electrode (e.g., the drain D) of the second transistor MOS2 and a portion of the gate Gate of the second transistor MOS2 extend to the third hollowed-out region LK3.

In an exemplary embodiment, as shown in FIG. 13, the second transistor MOS2 extends from the third hollowed-out region LK3 to a gap between the first portion CPW-1 of the coplanar waveguide and the second portion CPW-2 of the coplanar waveguide, and also into the fifth hollowed-out region LK5.

In an exemplary embodiment, the coplanar waveguide is grounded. As shown in FIG. 13, the second electrode (e.g., the drain D) of the third transistor MOS3 is electrically connected to the ground terminal GND through the second portion CPW-2 of the coplanar waveguide.

In at least one embodiment of the disclosure, in the case where the switch sub-circuit includes a fourth switch unit DY4, a fifth switch unit DY5, a sixth switch unit DY6 and a seventh switch unit DY7, as shown in FIG. 15, the first portion CPW-1 of the coplanar waveguide includes a sixth hollowed-out region LK6 and a seventh hollowed-out region LK7, and the second portion CPW-2 of the coplanar waveguide includes an eighth hollowed-out region LK8 and a ninth hollowed-out region LK9. The sixth hollowed-out region LK6 is connected to the seventh hollowed-out region LK7, and the eighth hollowed-out region LK8 is connected to the ninth hollowed-out region LK9. A body portion of the fifth transistor MOS5 and a body portion of the sixth transistor MOS6 are located in the gap.

The fourth transistor MOS4 and the fourth resistor R4 are located in the eighth hollowed-out region LK8.

A portion of the first semiconductor pattern 11 (AL) of the fifth transistor MOS5, a portion of a first electrode (e.g., the source S) of the fifth transistor MOS5, a fifth resistor R5, and a DC pad electrically connected to the fifth power supply device DC5 are located in the sixth hollowed-out region LK6.

A portion of the first semiconductor pattern 11 (AL) of the sixth transistor MOS6 and a portion of a first electrode (e.g., the source S) of the sixth transistor MOS6 are located in the seventh hollowed-out region LK7. A portion of the first semiconductor pattern 11 (AL) of the sixth transistor MOS6, a portion of a first electrode (e.g., the source S) of the sixth transistor MOS6, a sixth resistor R6, and a DC pad electrically connected to the sixth power supply device DC6 are located in the ninth hollowed-out region LK9.

A body portion of the seventh transistor MOS7 and a body portion of the seventh resistor R7 are located at the seventh hollowed-out region LK7.

In an exemplary embodiment, as shown in FIG. 15, a portion of a first semiconductor pattern 11 (AL) of the fifth transistor MOS5, a portion of a first electrode (e.g., the source S) of the fifth transistor MOS5, and a portion of a second electrode (e.g., the drain D) of the fifth transistor MOS5 are located in the sixth hollowed-out region LK6. A portion of the first semiconductor pattern 11 (AL) of the fifth transistor MOS5, a portion of the first electrode (e.g., the source S) of the fifth transistor MOS5, and a portion of the second electrode (e.g., the drain D) of the fifth transistor MOS5 are located in the eighth hollowed-out region LK8.

In an exemplary embodiment, as shown in FIG. 15, a portion of a first semiconductor pattern 11 (AL) of the sixth transistor MOS6, a portion of a first electrode (e.g., the source S) of the sixth transistor MOS6, and a portion of a second electrode (e.g., the drain D) of the sixth transistor MOS6 are located in the seventh hollowed-out region LK7. A portion of the first semiconductor pattern 11 (AL) of the sixth transistor MOS6, a portion of the first electrode (e.g., the source S) of the sixth transistor MOS6, and a portion of the second electrode (e.g., the drain D) of the sixth transistor MOS6 are located in the ninth hollowed-out region LK9.

In an exemplary embodiment, the coplanar waveguide is connected to ground. As shown in FIG. 15, the second electrode (e.g., the drain D) of the fourth transistor MOS4 is electrically connected to the ground terminal GND through the second portion CPW-2 of the coplanar waveguide. The second electrode (e.g., the drain D) of the seventh transistor MOS7 is electrically connected to the ground terminal GND through the first portion CPW-1 of the coplanar waveguide.

The shape and size of the planar pattern formed by the outer contours of the sixth hollowed-out region LK6, the seventh hollowed-out region LK7, the eighth hollowed-out region LK8, and the ninth hollowed-out region LK9 described above are not limited herein, and are determined according to the arrangement design of the devices in the switch sub-circuit.

An embodiment of the disclosure provides an RF chip including a switch structure as described in any one of the preceding.

In the RF chip provided by the embodiment of the disclosure, the silicon material layer 1 is directly provided on a glass substrate 100, and the ion doping concentration in the local region of the silicon material layer 1 is greater than or equal to 1×10¹⁸ cm⁻³. Thus, in the actual preparation process, after annealing the silicon material layer 1 by a low-temperature process, the activation of impurities can be achieved, and the local region of the silicon material layer 1 can be conducted. In addition, by directly bonding the silicon material layer 1 to the glass substrate 100, the leakage of the RF signal can be greatly reduced and the signal transmission stability of the switch structure can be improved, compared with the switch structure of the SOI technology.

An embodiment of the disclosure provides a method for preparing a switch structure applied to the preparation of the above switch structure, the method includes steps S01-S04.

In S01, a glass substrate 100 is provided.

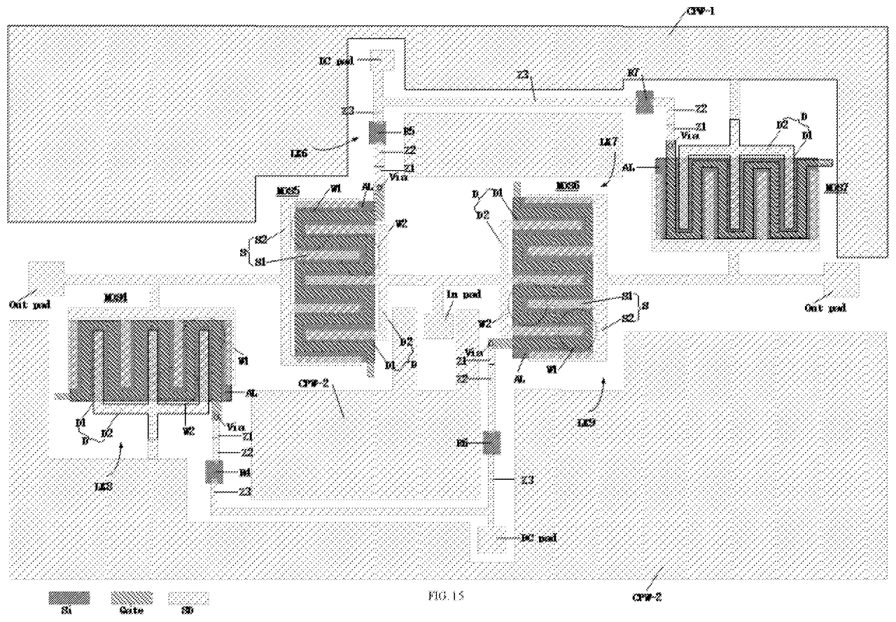

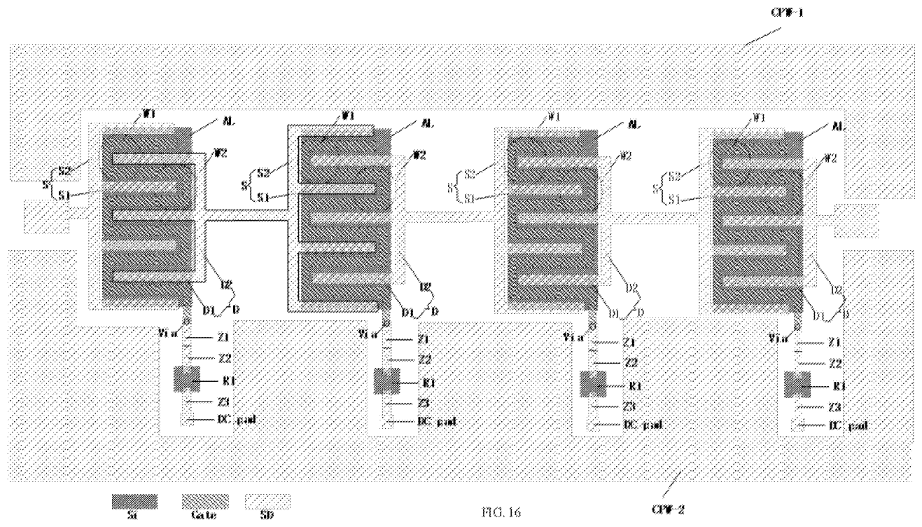

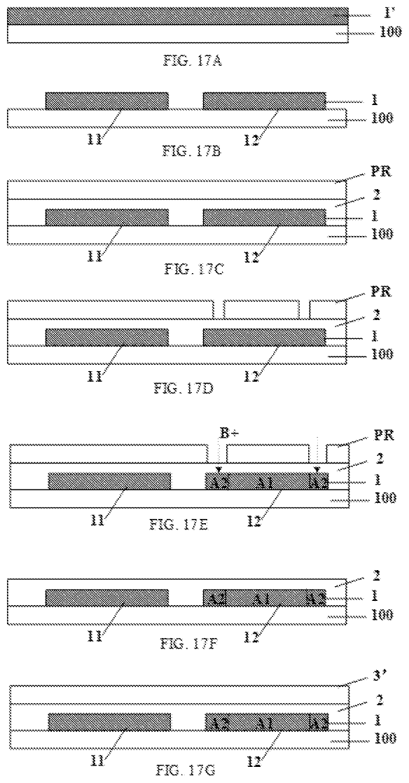

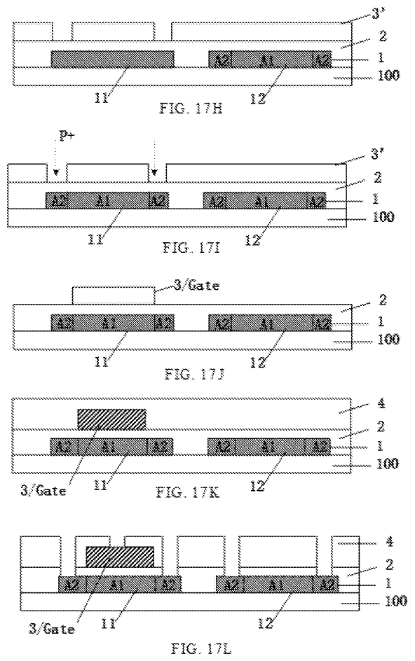

In S02, as shown in FIG. 17A, a monocrystalline silicon thin film 1′ is bonded to the glass substrate 100.

In the actual bonding process, a negative voltage is applied to the glass substrate 100, and a positive voltage is applied to the silicon material layer 1 (monocrystalline silicon thin film 1′). At a predetermined temperature and pressure, atoms near the interface between the glass substrate 100 and the silicon material layer 1 (monocrystalline silicon thin film 1′) migrate to each other and move to each other's film layer, thereby achieving the bonding of the glass substrate 100 and the silicon material layer 1 (monocrystalline silicon thin film 1′). The difference between voltages applied on the glass substrate 100 and the silicon material layer 1 (monocrystalline silicon thin film 1′) is approximately 200 V, and the predetermined temperature is 200° C.-400° C. The specific details of bonding can refer to the introduction of the bonding process in the related art, which will not be elaborated herein.

In S03, as shown in FIG. 17B, the monocrystalline silicon thin film 1′ is patterned to obtain a first semiconductor pattern 11 and a second semiconductor pattern 12.

In S04, ion implantation is performed on a local region of the first semiconductor pattern 11 and a local region of the second semiconductor pattern 12 respectively, and annealing treatment is performed on the first semiconductor pattern 11 and the second semiconductor pattern 12 at a predetermined temperature, so that the first semiconductor pattern 11 and the second semiconductor pattern 12 each include conducted regions (for example, the region marked with A2, as shown in FIG. 9). An ion implantation dose of the conducted region A1 ranges from 3×1015 cm⁻³ to 9×10¹⁵ cm⁻³, an ion doping concentration of the conducted region A2 is greater than or equal to 1×10¹⁸ cm⁻³, and the predetermined temperature is less than 650° C.

Illustratively, the predetermined temperature may be 550° C. to 600° C. For example, the predetermined temperature may be 560° C., 570° C., 580° C., or 590° C.

In the method for preparing the switch structure provided by the embodiment of the disclosure, the silicon material layer 1 is directly provided on a glass substrate 100, and the ion doping concentration in the local region of the silicon material layer 1 is greater than or equal to 1×10¹⁸ cm⁻³. Thus, in the actual preparation process, after annealing the silicon material layer 1 by a low-temperature process, the activation of impurities can be achieved, and the local region of the silicon material layer 1 can be conducted. In addition, by directly bonding the silicon material layer 1 to the glass substrate 100, the leakage of the RF signal can be greatly reduced and the signal transmission stability of the switch structure can be improved, compared with the switch structure of the SOI technology.

A method for preparing the switch structure will be described and explained with reference to FIGS. 17A to 17L and FIG. 9.

1) An SOG sheet (a substrate bonding a monocrystalline silicon thin film 1′ to a glass substrate 100) as shown in FIG. 17A is provided for pre-cleaning. The monocrystalline silicon in the top layer is p-type silicon with a resistivity of 8-10 Ω·m.
2) A photoresist thin film (PR) is formed and subjected to exposure and etching to obtain a mask plate formed by the photoresist. The monocrystalline silicon thin film 1′ is subjected to etching treatment by the mask plate (for example, an ICP etching process) and patterning to obtain a first semiconductor pattern 11 and a second semiconductor pattern 12 as shown in FIG. 17B.
3) As shown in FIG. 17C, a gate insulating layer (GI) 2 is deposited by a PECVD (Plasma Enhanced Chemical Vapor Deposition) process, and the material of the gate insulating layer 2 can be silicon nitride, silicon oxide, or other dielectric material.
4) As shown in FIG. 17C, a conductive layer is formed by a sputter process. The conductive layer is a mask plate implanted with boron ion (in practice, a photoresist PR as shown in FIG. 17C can also be used instead of the conductive layer as a mask plate for subsequent process).
5) As shown in FIG. 17D, the photoresist PR is patterned to define an ion implantation region in the second semiconductor pattern 12.
6) As shown in FIG. 17E, boron ion (B+) implantation is performed at an implantation dose greater than or equal to 3*e¹⁵ cm⁻².
7) The photoresist PR as the mask plate is removed to obtain a structure as shown in FIG. 17F.
8) As shown in FIG. 17G, a gate thin film 3′ is formed by the sputter process.
9) As shown in FIG. 17H, the gate thin film 3′ is patterned to define an implantation region in the first semiconductor pattern 11.
10) As shown in FIG. 17I, phosphorus ion (P+) implantation is performed at an implantation dose greater than or equal to 3*e¹⁵ cm⁻². After annealing at a temperature of 600° C. for 1 h, p+ highly doped regions are formed in two conducted regions A2 of the second semiconductor pattern 12, and n+ highly doped regions are formed in two conducted regions A2 of the first semiconductor pattern 11.
11) The gate thin film 3′ as shown in FIG. 17I is patterned for the second time to obtain the gate Gate of the transistor as shown in FIG. 17J.
12) As shown in FIG. 17K, an Inter Level Dielectric (ILD) layer 4 is formed by a PECVD process, and the material of the ILD layer 4 can be silicon nitride, silicon oxide, or other dielectric material.
13) As shown in FIG. 17L, the ILD layer 4 and the gate insulating layer 2 are patterned to define regions of contact holes (also called via holes).
14) A source-drain conductive film is formed by the sputter process.
15) The source-drain conductive thin film is patterned to obtain a source-drain conductive layer 5 as shown in FIG. 9. The source-drain conductive layer 5 includes a source and a drain of a transistor, a coplanar waveguide CPW and a plurality of first traces Z1, a plurality of second traces Z2, and a plurality of third traces Z3.

The foregoing is only a specific implementation of the disclosure, but the scope of protection of the disclosure is not limited thereto. Any changes or replacements easily conceivable by any person skilled in the art within the technical scope disclosed in the disclosure should be covered by the scope of protection of the disclosure. Therefore, the scope of protection of the disclosure should be subject to the scope of protection of the claims.

1. A switch structure, comprising:
a glass substrate;
at least one switch sub-circuit located on the glass substrate, wherein the switch sub-circuit comprises at least one switch unit; the switch unit comprises a transistor and a resistor; a gate of the transistor is electrically connected to the resistor; the resistor is electrically connected to a power supply device; a first electrode of at least one transistor is electrically connected to an in pad, and a second electrode of at least one transistor is electrically connected to an out pad; and
a silicon material layer located on and bonded to the glass substrate, wherein the silicon material layer comprises a conducted region; a portion of the conducted region is configured to electrically connect the gate of the transistor and the resistor, and an ion doping concentration of the conducted region is greater than or equal to 1×10¹⁸ cm⁻³.

2. The switch structure according to claim 1, wherein at least one of the first electrode of the transistor, the second electrode of the transistor, and the gate of the transistor comprises an interdigital structure.

3. The switch structure according to claim 2, wherein the first electrode of the transistor, the second electrode of the transistor, and the gate of the transistor all comprise the interdigital structure, and an orthographic projection of the gate of the transistor partially overlaps with an orthographic projection of one of the first electrode of the transistor and the second electrode of the transistor on the glass substrate.

4. (canceled)

5. The switch structure according to claim 3, wherein a channel width-to-length ratio of the transistor is greater than or equal to 5000.

6. The switch structure according to claim 2, wherein the silicon material layer comprises a monocrystalline silicon sub-layer.

7. (canceled)

8. The switch structure according to claim 5, wherein the switch sub-circuit comprises an in pad and an out pad.

9. The switch structure according to claim 8, wherein the switch sub-circuit comprises a first switch unit; the first switch unit comprises a first transistor and a first resistor; and the power supply device comprises a first power supply device; and
a first electrode of the first transistor is electrically connected to the in pad; a second electrode of the first transistor is electrically connected to the out pad; a gate of the first transistor is electrically connected to a first terminal of the first resistor; and the first power supply device is electrically connected to a ground terminal and a second terminal of the first resistor, respectively.

10. The switch structure according to claim 8, wherein the switch sub-circuit comprises a second switch unit and a third switch unit; the second switch unit comprises a second transistor and a second resistor; the third switch unit comprises a third transistor and a third resistor; the power supply device comprises a second power supply device and a third power supply device;
a first electrode of the second transistor and a first electrode of the third transistor are electrically connected to the in pad; a second electrode of the second transistor is electrically connected to the out pad; a gate of the second transistor is electrically connected to a first terminal of the second resistor; and the second power supply device is electrically connected to a ground terminal and a second terminal of the second resistor, respectively; and
a gate of the third transistor is electrically connected to a first terminal of the third resistor; the third power supply device is electrically connected to a ground terminal and a second terminal of the third resistor, respectively; and a second electrode of the third transistor is electrically connected to the ground terminal.

11. The switch structure according to claim 5, wherein the switch sub-circuit comprises a fourth switch unit, a fifth switch unit, a sixth switch unit and a seventh switch unit;
the fourth switch unit comprises a fourth transistor and a fourth resistor; the fifth switch unit comprises a fifth transistor and a fifth resistor; the sixth switch unit comprises a sixth transistor and a sixth resistor; the seventh switch unit comprises a seventh transistor and a seventh resistor; and the power supply device comprises a fifth power supply device and a sixth power supply device; and
wherein the fourth switch unit and the sixth switch unit share the sixth power supply device, and the fifth switch unit and the seventh switch unit share the fifth power supply device.

12. The switch structure according to claim 11, wherein the switch sub-circuit comprises one in pad and two out pads.

13. The switch structure according to claim 11, wherein the switch sub-circuit comprises two in pads and one out pad.

14. The switch structure according to claim 12, wherein a first electrode of the fourth transistor and a first electrode of the fifth transistor are electrically connected to a first one of the out pads; a second electrode of the fourth transistor is electrically connected to a ground terminal; a second electrode of the fifth transistor is electrically connected to the in pad; a gate of the fourth transistor is electrically connected to a first terminal of the fourth resistor; and a gate of the fifth transistor is electrically connected to a first terminal of the fifth resistor; and
a first electrode of the sixth transistor and a first electrode of the seventh transistor are electrically connected to a second one of the out pads; a second electrode of the sixth transistor is electrically connected to the in pad; a second electrode of the seventh transistor is electrically connected to the ground terminal; a gate of the sixth transistor is electrically connected to a first terminal of the sixth resistor; and a gate of the seventh transistor is electrically connected to a first terminal of the seventh resistor.

15. (canceled)

16. (canceled)

17. (canceled)

18. The switch structure according to claim 9, wherein the switch structure comprises:
the silicon material layer comprising a first semiconductor pattern and a second semiconductor pattern;
a gate insulating layer covering the silicon material layer;
a gate layer located on a side of the gate insulating layer away from the glass substrate and comprising the gate of the transistor;
an inter level dielectric layer covering the gate layer; and
a source-drain conductive layer located on a side of the inter level dielectric layer away from the glass substrate and comprising the first electrode and the second electrode of the transistor; and
wherein the first semiconductor pattern and the second semiconductor pattern comprise a semiconductor region and conducted regions located on two sides of the semiconductor region; the first electrode of the transistor is electrically connected to one of the conducted regions in the first semiconductor pattern; the second electrode of the transistor is electrically connected to the other one of the conducted regions in the first semiconductor pattern; the semiconductor region in the first semiconductor pattern serves as a channel region of the transistor; and the semiconductor region in the second semiconductor pattern serves as the resistor.

19. The switch structure according to claim 18, wherein the source-drain conductive layer further comprises a first trace, a second trace and a third trace, wherein the first trace is electrically connected to one of the second trace and the third trace; and
the first trace is electrically connected to the gate of the transistor; the second trace is electrically connected to one of the conducted regions in the second semiconductor pattern; and the third trace is electrically connected to the other one of the conducted regions in the second semiconductor pattern.

20. The switch structure according to claim 19, wherein for at least one transistor, a first electrode of the transistor comprises an interdigital structure;
the first electrode of the transistor comprises a first connection portion and N-2 first extension portions arranged in the same row; an extension direction of the first connection portion intersects with an extension direction of the first extension portions; an arrangement direction of the first extension portions is the same as the extension direction of the first connection portion; the first connection portion is located on the same side of each of the first extension portions and connects each of the first extension portions together; N is a positive integer and is greater than or equal to 4; and
an orthographic projection of each of the first extension portions on the glass substrate at least partially overlaps with an orthographic projection of the first semiconductor pattern on the glass substrate.

21. The switch structure according to claim 20, wherein for at least one transistor, a second electrode of the transistor comprises an interdigital structure;
the second electrode of the transistor comprises a second connection portion and N-3 second extension portions arranged in the same row; an extension direction of the second connection portion is the same as the extension direction of the first connection portion; an arrangement direction of the second extension portions is the same as the arrangement direction of the first extension portions; the second connection portion is located on the same side of each of the second extension portions and connects each of the second extension portions together; and
an orthographic projection of each of the second extension portions on the glass substrate at least partially overlaps with the orthographic projection of the first semiconductor pattern on the glass substrate.

22. The switch structure according to claim 21, wherein for at least one transistor, a gate of the transistor comprises an interdigital structure;
the gate of the transistor comprises a third connection portion and N third extension portions arranged in the same row; an extension direction of the third connection portion intersects with an extension direction of the third extension portions; the third connection portion is located at the same side of each of the third extension portions and connects each of the third extension portions together; an orthographic projection of each of the third extension portions on the glass substrate at least partially overlaps with the orthographic projection of the first semiconductor pattern on the glass substrate; and an orthographic projection of the third connection portion on the glass substrate partially overlaps with orthographic projections of all the second extension portions on the glass substrate; and
wherein the orthographic projections of the first extension portions, the third extension portions, and the second extension portions on the glass substrate are alternately arranged in sequence along the extension direction of the third connection portion.

23. (canceled)

24. (canceled)

25. The switch structure according to claim 22, wherein the source-drain conductive layer further comprises a coplanar waveguide, the in pad, the out pad, and at least one DC pad; the DC pad and the power supply device are the same in quantity and are electrically connected in a one-to-one correspondence; the coplanar waveguide comprises a first portion and a second portion with a gap therebetween; the in pad and the out pad are located within the gap; and
orthographic projections of the transistor, the resistor, the in pad, the out pad and the DC pad on the glass substrate do not overlap with an orthographic projection of the coplanar waveguide on the glass substrate, respectively; and the coplanar waveguide is electrically connected to the ground terminal.

26. (canceled)

27. (canceled)

28. (canceled)

29. A radio frequency chip, comprising the switch structure according to claim 1.

30. A method for preparing a switch structure, applied to prepare the switch structure according to claim 1, wherein the method comprises:
providing a glass substrate;
bonding a monocrystalline silicon thin film to the glass substrate;
patterning the monocrystalline silicon thin film to obtain a first semiconductor pattern and a second semiconductor pattern; and
performing ion implantation on a local region of the first semiconductor pattern and a local region of the second semiconductor pattern respectively, and performing annealing treatment on the first semiconductor pattern and the second semiconductor pattern at a predetermined temperature, so that the first semiconductor pattern and the second semiconductor pattern comprise a conducted region; an ion implantation dose of the conducted region ranges from 3×10¹⁵ cm⁻³ to 9×10¹⁵ cm⁻³, an ion doping concentration of the conducted region is greater than or equal to 1×10¹⁸ cm⁻³, and the predetermined temperature is less than 650° C.
